(19) United States
(12) Patent Application Publication
(10) Pub. No.: US 2018/0175247 A1
(43) Pub. Date: Jun. 21, 2018

(54) SEMICONDUCTOR LIGHT-EMITTING DEVICE

(71) Applicant: Samsung Electronics Co., Ltd., Suwon-si (KR)

(72) Inventors: Ju-heon YOON, Seoul (KR); Jae-in Sim, Yongin-si (KR); Gi-bum Kim, Yongin-si (KR)

(73) Assignee: Samsung Electronics Co., Ltd., Suwon-si (KR)

(21) Appl. No.: 15/609,653

(22) Filed: May 31, 2017

(30) Foreign Application Priority Data
Dec. 15, 2016 (KR) 10-2016-0171668

(51) Int. Cl. H01L 33/40; H01L 33/60; H01L 33/62

(52) U.S. Cl. CPC H01L 33/405; H01L 33/62; H01L 33/60

(57) ABSTRACT

A semiconductor light-emitting device includes a light-emitting structure comprising a first semiconductor layer, an active layer, and a second semiconductor layer; a reflective electrode layer covering a top surface of the second semiconductor layer; an insulating structure covering a region of the top surface of the second semiconductor layer, the region being around the reflective electrode layer; a first interconnection conductive layer contacting a contact region of the first semiconductor layer through the insulating structure and, together with the insulating structure, constituting an omni-directional reflector (ODR) structure; and a second interconnection conductive layer contacting the reflective electrode layer through the insulating structure.

### CROSS-REFERENCE TO RELATED APPLICATION

This application claims the benefit of priority from Korean Patent Application No. 10-2016-0171668, filed on Dec. 15, 2016, in the Korean Intellectual Property Office, the disclosure of which is incorporated herein in its entirety by reference.

### BACKGROUND

The inventive concepts relate to a light-emitting device, and more particularly, to a semiconductor light-emitting device including an electrode on a semiconductor layer.

A light-emitting diode (LED) which is a kind of semiconductor light-emitting device is widely applied to various light sources used for backlights and the like, as well as for lighting, signalers, large-size displays, and the like. As the LED lighting market expands and a range of applications for LED lighting extends to high current and high power applications, it may be advantageous to develop a technique for improving the reliability of an electrode electrically connecting a semiconductor layer of an LED to a structure external to the LED, such as a module or a package, and for improving light extraction efficiency of a device.

### SUMMARY

The inventive concepts relate to a semiconductor light-emitting device capable of improving the reliability of an electrode electrically connecting a semiconductor layer of an LED to a structure external to the LED, such as a module or a package, and of improving light extraction efficiency of a device.

According to an example of the inventive concepts, there is provided a semiconductor light-emitting device including: a light-emitting structure including a first semiconductor layer, an active layer, and a second semiconductor layer; a reflective electrode layer covering a top surface of the second semiconductor layer; an insulating structure covering a region of the top surface of the second semiconductor layer, the region being around the reflective electrode layer; a first interconnection conductive layer contacting a contact region of the first semiconductor layer through the insulating structure and, together with the insulating structure, constituting an omni-directional reflector (ODR) structure; and a second interconnection conductive layer contacting the reflective electrode layer through the insulating structure.

According to another example of the inventive concepts, there is provided a semiconductor light-emitting device including: a light-emitting structure including a first semiconductor layer, an active layer, and a second semiconductor layer; a reflective electrode layer covering a first region of a top surface of the second semiconductor layer; a first insulating pattern covering a second region of the top surface of the second semiconductor layer, the second region being around the first region; a second insulating pattern covering the first insulating pattern and the reflective electrode layer on the top surface of the second semiconductor layer; a first interconnection conductive layer, which contacts, or is in contact with, a contact region of the first semiconductor layer through the first insulating pattern and the second insulating pattern and faces the top surface of the second semiconductor layer with the first insulating pattern and the second insulating pattern being between the first interconnection conductive layer and the top surface of the second semiconductor layer, the first interconnection conductive layer, together with the first insulating pattern and the second insulating pattern, constituting a first local ODR structure; and a second interconnection conductive layer contacting the reflective electrode layer through the second insulating pattern and spaced apart from the first interconnection conductive layer.

According to the inventive concepts, the semiconductor light-emitting device provides an ODR structure by using insulating patterns covering a top surface of a mesa structure of a light-emitting structure, which is a semiconductor region not covered with a reflective electrode layer, and using an interconnection conductive layer covering the insulating patterns, thereby having a structure in which at least a portion of light emitted above the semiconductor region around the reflective electrode layer may be reflected by the ODR structure. Therefore, the semiconductor light-emitting device allows total reflection to be maximized and luminous flux to be improved. In addition, the semiconductor light-emitting device has a structure in which the reflective electrode layer is capped with a multilayer insulating structure, whereby the reliability of the reflective electrode layer may be improved by reducing or suppressing migration or agglomeration of a metal material in the reflective electrode layer due to excellent adhesion between the semiconductor layer of the mesa structure and the insulating structure, and the semiconductor light-emitting device may have a relatively stable structure due to physically enhanced adhesion between the reflective electrode layer and the mesa structure.

Some example embodiments relate to a semiconductor light-emitting device including a light-emitting structure, a reflective electrode layer on the light-emitting structure, an insulating structure on a region of the light-emitting structure around the reflective electrode layer, an omni-directional reflector (ODR) structure including a first interconnection conductive layer and the insulating structure, and a second interconnection conductive layer in contact with the reflective electrode layer through the insulating structure.

### BRIEF DESCRIPTION OF THE DRAWINGS

Embodiments of the inventive concepts will be more clearly understood from the following detailed description taken in conjunction with the accompanying drawings in which:

FIG. 1A is a planar layout diagram illustrating main components of a semiconductor light-emitting device according to embodiments, and FIG. 1B is an enlarged cross-sectional view taken along a line B-B′ of FIG. 1A;

FIG. 2 is a cross-sectional view illustrating a semiconductor light-emitting device according to other example embodiments;

FIGS. 3A, 4A, 5A, 6A, 7A, 8A, 9A and 10A are plan views illustrating processes, for example sequential processes of a method of fabricating a semiconductor light-emitting device, according to embodiments, and FIGS. 3B, 4B, 5B, 6B, 7B, 8B, 9B and 10B are cross-sectional views taken along a line B-B′ of FIGS. 3A, 4A, 5A, 6A, 7A, 8A, 9A and 10A, respectively;

FIG. 11A is a plan view illustrating main components of a semiconductor light-emitting device according to further embodiments and a method of fabricating the semiconductor light-emitting device, and FIG. 11B is a cross-sectional view taken along a line B-B′ of FIG. 11A;

FIG. 12 is a cross-sectional view illustrating an example of a light-emitting device package including a semiconductor light-emitting device according to embodiments;

FIG. 13 is a schematic plan view illustrating an example of a dimming system including a semiconductor light-emitting device according to embodiments; and

FIG. 14 is a block diagram of a display device including a semiconductor light-emitting device according to embodiments.

### DETAILED DESCRIPTION OF THE EMBODIMENTS

Hereinafter, embodiments of the inventive concepts will be described in detail with reference to the accompanying drawings. In the accompanying drawings, variations of illustrated shapes may be anticipated depending upon fabrication techniques and/or tolerances. Thus, embodiments of the inventive concepts are not to be construed as being limited to the specific shapes of regions illustrated herein, and are to be construed as including, for example, variations of shapes caused in the process of fabrication. Embodiments of the inventive concepts may be performed alone or in combination. In the accompanying drawings, the thickness or size of each layer may be exaggerated for convenience and clarity. Like components will be denoted by like reference numerals throughout the specification, and repeated descriptions thereof will be omitted.

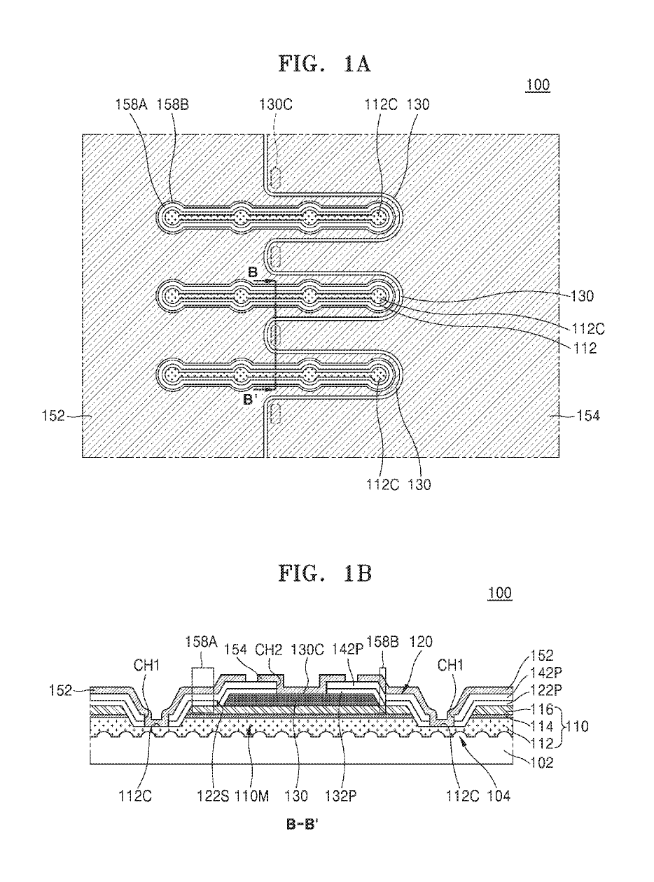

FIGS. 1A and 1B are diagrams illustrating a semiconductor light-emitting device according to embodiments, and in particular, FIG. 1A is a planar layout diagram illustrating main components of a semiconductor light-emitting device 100, and FIG. 1B is an enlarged cross-sectional view taken along a line B-B′ of FIG. 1A.

Referring to FIGS. 1A and 1B, the semiconductor light-emitting device 100 includes a substrate 102, and a mesa structure 110M including a light-emitting structure 110 on the substrate 102.

The light-emitting structure 110 includes a first semiconductor layer 112, an active layer 114, and a second semiconductor layer 116.

An uneven pattern 104 is formed on a surface of the substrate 102 facing the first semiconductor layer 112. The uneven pattern 104 is formed on the surface of the substrate 102, whereby internal quantum efficiency may be improved due to improved crystallinity and reduced defect density of semiconductor layers on the substrate 102, and light extraction efficiency of the semiconductor light-emitting device 100 may be improved due to an increase in extraction efficiency by diffuse reflection of light on the surface of the substrate 102.

The substrate 102 may include a transparent substrate. For example, the substrate 102 may include sapphire (Al₂O₃), gallium nitride (GaN), silicon carbide (SiC), gallium oxide (Ga₂O₃), lithium gallium oxide (LiGaO₂), lithium aluminum oxide (LiAlO₂), or magnesium aluminum oxide (MgAl₂O₄).

Each of, or at least one of the first semiconductor layer 112, the active layer 114, and the second semiconductor layer 116 may include a gallium nitride-based compound semiconductor represented by InxAlyGa(1-x-y)N (0≤x≤1, 0≤y≤1, 0≤x+y≤1).

In some example embodiments, the first semiconductor layer 112 may include an n-type GaN layer supplying electrons to the active layer 114 according to the supply of power. The n-type GaN layer may include an n-type impurity including a group IV element. The n-type impurity may include Si, Ge, Sn, or the like.

In some example embodiments, the second semiconductor layer 116 may include a p-type GaN layer supplying holes to the active layer 114 according to the supply of power. The p-type GaN layer may include a p-type impurity including a group II element. In some example embodiments, the p-type impurity may include Mg, Zn, Be, or the like.

The active layer 114 emits light having certain energy by recombination of electrons and holes. The active layer 114 may have a structure in which a quantum well layer and a quantum barrier layer are alternately stacked at least once. The quantum well layer may have a single quantum well structure or a multi-quantum well structure. In some example embodiments, the active layer 114 may include u-AlGaN. In some other example embodiments, the active layer 114 may include a multi-quantum well structure of GaN/AlGaN, InAlGaN/InAlGaN, or InGaN/AlGaN. To improve luminous efficiency of the active layer 114, the depth of a quantum well, the number of pairs of stacked quantum well and quantum barrier layers, the thicknesses of quantum well and quantum barrier layers, or the like in the active layer 114 may be changed.

In some example embodiments, the semiconductor light-emitting device 100 may further include a nitride semiconductor thin film (not shown) between the substrate 102 and the light-emitting structure 110. The nitride semiconductor thin film may serve as a buffer layer buffering lattice mismatch between the substrate 102 and the first semiconductor layer 112. The nitride semiconductor thin film may include a gallium nitride-based compound semiconductor represented by InxAlyGa(1-x-y)N (0≤x≤1, 0≤y≤1, 0≤x+y≤1). In some example embodiments, the nitride semiconductor thin film may include GaN or AlN. In some other example embodiments, the nitride semiconductor thin film may include superlattice layers of AlGaN/AlN.

The semiconductor light-emitting device 100 includes a reflective electrode layer 130 covering a top surface of the second semiconductor layer 116. The reflective electrode layer 130 may reflect light emitted from the active layer 114 of the mesa structure 110M. The reflective electrode layer 130 may include a metal or alloy having high reflectivity in a wavelength range of light emitted from the active layer 114. In some example embodiments, the reflective electrode layer 130 may include Ag, Al, combinations thereof, or alloys thereof. Here, the Al alloys may include Al and a metal having a higher work function than Al. In some other example embodiments, the reflective electrode layer 130 may include Al, and at least one metal selected from among Ni, Au, Ag, Ti, Cr, Pd, Cu, Pt, Sn, W, Rh, Ir, Ru, Mg, and Zn or an alloy including the at least one metal. In some further embodiments, the reflective electrode layer 130 may include a metal layer simultaneously or contemporaneously having ohmic properties and light reflection properties. In some yet other example embodiments, the reflective electrode layer 130 may include a multilayer film including a first metal film (not shown) having ohmic properties and a second metal film (not shown) having light reflection properties. The first metal film may include Pt, Pd, Ni, Au, Ti, or an alloy or multilayer metal film including at least one thereof. The second metal film may include Ag, Al, or an alloy or multilayer metal film including at least one thereof. For example, the reflective electrode layer 130 may include an Ag/Ni/Ti or Ni/Ag/Pt/Ti/Pt stacked structure, without being limited thereto.

The reflective electrode layer 130 may contact the second semiconductor layer 116. However, the inventive concepts are not limited thereto. In some example embodiments, another semiconductor layer (not shown) may further be between the second semiconductor layer 116 and the reflective electrode layer 130.

The semiconductor light-emitting device 100 includes an insulating structure 120 covering the top surface of the second semiconductor layer 116 around the reflective electrode layer 130. The insulating structure 120 includes a first insulating pattern 122P, which covers the top surface of the second semiconductor layer 116 around the reflective electrode layer 130, a second insulating pattern 142P, which is on the first insulating pattern 122P and covers the top surface of the second semiconductor layer 116 and the reflective electrode layer 130, and an insulating capping pattern 132P between the reflective electrode layer 130 and the second insulating pattern 142P and between the top surface of the second semiconductor layer 116 and the second insulating pattern 142P.

Each of, or at least one of the first insulating pattern 122P, the second insulating pattern 142P, and the insulating capping pattern 132P may include SiO₂, Si₃N₄, MgF₂, or combinations thereof, without being limited thereto. In some example embodiments, the insulating capping pattern 132P may include a material that is the same as a material constituting the first insulating pattern 122P. In some example embodiments, the first insulating pattern 122P and the second insulating pattern 142P may include different materials from each other. In some other example embodiments, although including the same material, the first insulating pattern 122P and the second insulating pattern 142P may be formed by different film forming processes from each other.

In some example embodiments, a refractive index of the first insulating pattern 122P may be less than a refractive index of the second insulating pattern 142P. In one example, each of, or at least one of, the first insulating pattern 122P and the second insulating pattern 142P may include SiO₂. In another example, the first insulating pattern 122P may include MgF2, and the second insulating pattern 142P may include SiO₂. In a further example, the first insulating pattern 122P may include SiO₂, and the second insulating pattern 142P may include Si₃N₄. However, the inventive concepts are not limited to the materials set forth above as examples.

The semiconductor light-emitting device 100 may include a first interconnection conductive layer 152 contacting a contact region 112C of the first semiconductor layer 112, and a second interconnection conductive layer 154 contacting a contact region 130C of the reflective electrode layer 130. The first interconnection conductive layer 152 may contact the contact region 112C through the first insulating pattern 122P and the second insulating pattern 142P. The second interconnection conductive layer 154 may contact the contact region 130C through the insulating capping pattern 132P and the second insulating pattern 142P. The contact region 130C is covered with the second interconnection conductive layer 154. In FIG. 1A, the contact region 130C is marked by a dashed line.

The first interconnection conductive layer 152 may extend so as to cover the contact region 112C of the first semiconductor layer 112 and a sidewall and a top surface of the mesa structure 110M. In addition, the first interconnection conductive layer 152 may extend so as to cover a portion of the top surface of the second semiconductor layer 116 of the mesa structure 110M, which is not covered with the reflective electrode layer 130, and a top surface of the reflective electrode layer 130.

The first interconnection conductive layer 152 may include a first reflective metal film contacting the contact region 112C of the first semiconductor layer 112. The second interconnection conductive layer 154 may include a second reflective metal film contacting the contact region 130C of the reflective electrode layer 130. Each of, or at least one of the first reflective metal film and the second reflective metal film may include Al, Ag, or combinations thereof.

In some example embodiments, each of, or at least one of the first reflective metal film and the second reflective metal film may include a plurality of metal layers. For example, each of, or at least one of first interconnection conductive layer 152 and the second interconnection conductive layer 154 may have a structure in which a reflective metal film, a metal barrier film, and a metal wiring film are stacked in this stated order. The reflective metal film may include Al, Ag, or combinations thereof. The metal barrier film may include Cr, Ti, or combinations thereof. The metal wiring film may include Cu, Cr, or combinations thereof. In some example embodiments, although each of, or at least one of first interconnection conductive layer 152 and the second interconnection conductive layer 154 may have a stacked structure of Al/Cr/Ti/Cr/Ti/Cu/Cr or a stacked structure of Ag/Cr/Ti/Cr/Ti/Cu/Cr, the inventive concepts is not limited to the examples set forth above, and various modifications and changes thereof may be made.

The first interconnection conductive layer 152, in conjunction with the first insulating pattern 122P, the insulating capping pattern 132P, and the second insulating pattern 142P, may constitute an omni-directional reflector (ODR) structure. The ODR structure may include a first local ODR structure 158A, which includes the first insulating pattern 122P, the second insulating pattern 142P, and the first interconnection conductive layer 152, and a second local ODR structure 158B, which includes the insulating capping pattern 132P, the second insulating pattern 142P, and the first interconnection conductive layer 152. In the semiconductor light-emitting device 100, at least a portion of light emitted from the active layer 114 through the top surface of the second semiconductor layer 116 around the reflective electrode layer 130 may be reflected by the first local ODR structure 158A and the second local ODR structure 158B.

The first insulating pattern 122P may contact the top surface of the second semiconductor layer 116. In addition, the refractive index of the first insulating pattern 122P may be less than the refractive index of the second insulating pattern 142P, thereby improving efficiency of light reflection by the first local ODR structure 158A.

The insulating capping pattern 132P may contact the top surface of the second semiconductor layer 116 around the reflective electrode layer 130. The refractive index of the insulating capping pattern 132P may be less than the refractive index of the second insulating pattern 142P, thereby improving efficiency of light reflection by the second local ODR structure 158B.

As shown in FIG. 1A, the first local ODR structure 158A may be interposed between the contact region 112C of the first semiconductor layer 112 and the reflective electrode layer 130 and have a ring shape surrounding the contact region 112C of the first semiconductor layer 112. The second local ODR structure 158B may be interposed between the reflective electrode layer 130 and the first local ODR structure 158A and have a ring shape surrounding the contact region 112C of the first semiconductor layer 112.

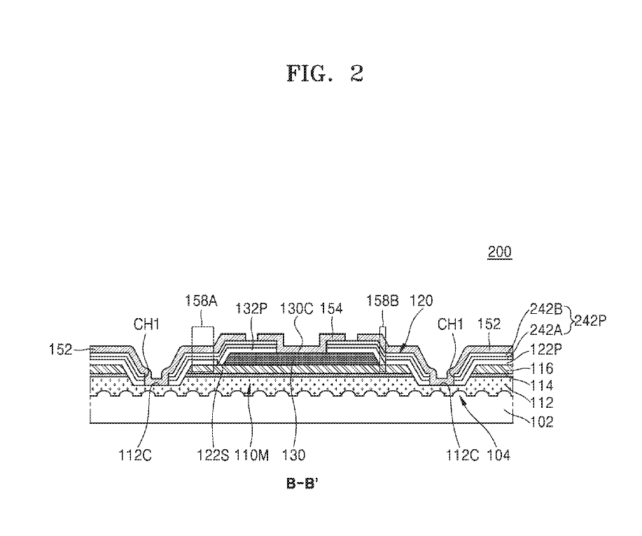

FIG. 2 is a cross-sectional view illustrating a semiconductor light-emitting device according to other example embodiments. Like in FIG. 1B, a configuration of a portion of the semiconductor light-emitting device, which corresponds to the cross-section taken along the line B-B′ of FIG. 1A, is shown in FIG. 2. In FIG. 2, the same reference numerals as in FIGS. 1A and 1B denote the same members, and thus further descriptions thereof are omitted.

Referring to FIG. 2, in a semiconductor light-emitting device 200, a second insulating pattern 242P includes two layers. The second insulating pattern 242P includes a lower second insulating pattern 242A and an upper second insulating pattern 242B. The lower second insulating pattern 242A and the upper second insulating pattern 242B may include different materials from each other. For example, although the lower second insulating pattern 242A and the upper second insulating pattern 242B may respectively include different materials selected from SiO₂ and Si₃N₄, the inventive concepts is not limited to the example set forth above. More detailed descriptions of the second insulating pattern 242P are substantially the same as those of the second insulating pattern 142P made with reference to FIGS. 1A and 1B.

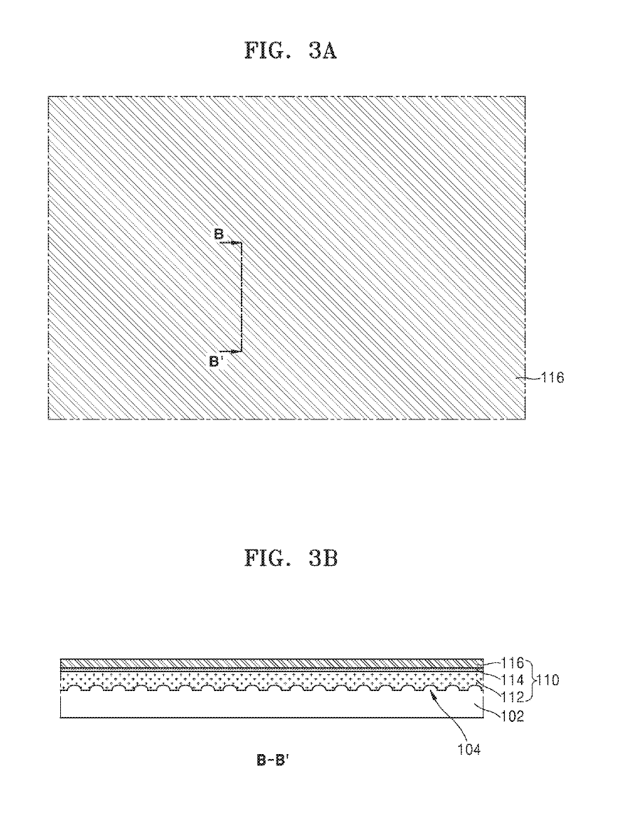

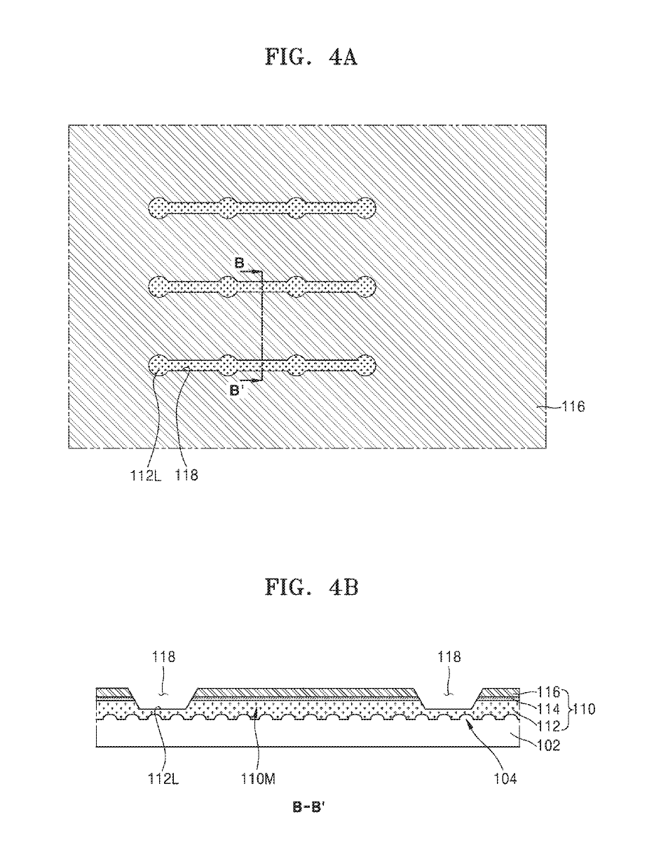

FIGS. 3A to 10B are diagrams illustrating processes, for example sequential processes, of a method of fabricating a semiconductor light-emitting device, according to embodiments, and in particular, FIGS. 3A, 4A, . . . , and 10A are plan views illustrating processes, for example sequential processes, of a method of fabricating the semiconductor light-emitting device 100 shown in FIGS. 1A and 1B, and FIGS. 3B, 4B, . . . , and 10B are enlarged cross-sectional views respectively taken along a line B-B′ of FIGS. 3A, 4A, . . . , and 10A. In FIGS. 3A to 10B, the same reference numerals as in FIGS. 1A and 1B denote the same members, and thus further descriptions thereof are omitted for simplicity.

Referring to FIGS. 3A and 3B, the light-emitting structure 110 including the first semiconductor layer 112, the active layer 114, and the second semiconductor layer 116 is formed on the substrate 102.

To form the light-emitting structure 110, the first semiconductor layer 112, the active layer 114, and the second semiconductor layer 116 may be formed in this stated order by a metal organic chemical vapor deposition (MOCVD), hydride vapor phase epitaxy (HVPE), or molecular beam epitaxy (MBE) process. The first semiconductor layer 112 may be an n-type semiconductor layer. The second semiconductor layer 116 may be a p-type semiconductor layer.

Referring to FIGS. 4A and 4B, each of, or at least one of the second semiconductor layer 116, the active layer 114, and the first semiconductor layer 112 may be partially etched, thereby forming a plurality of trenches 118 defining the mesa structure 110M of the light-emitting structure 110. The low surface 112L of the first semiconductor layer 112 may be exposed at bottom surfaces of the plurality of trenches 118.

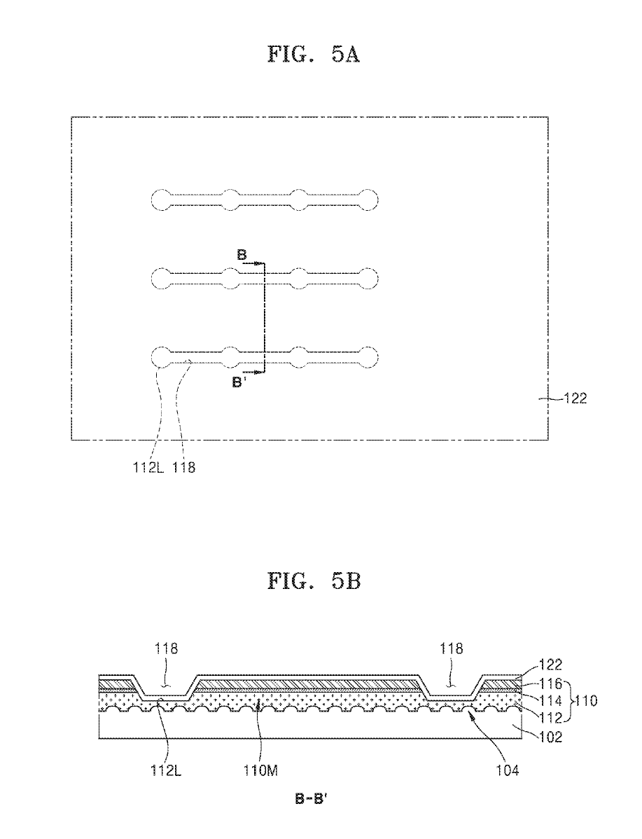

Referring to FIGS. 5A and 5B, a first insulating film 122 may be formed so as to cover an exposed surface of the mesa structure 110M and an inner wall of each of, or at least one of the plurality of trenches 118.

The first insulating film 122 may include SiO₂, Si₃N₄, MgF₂, or combinations thereof, without being limited thereto. In some example embodiments, the first insulating film 122 may be formed by a process of plasma enhanced chemical vapor deposition (PECVD), physical vapor deposition (PVD), or spin coating.

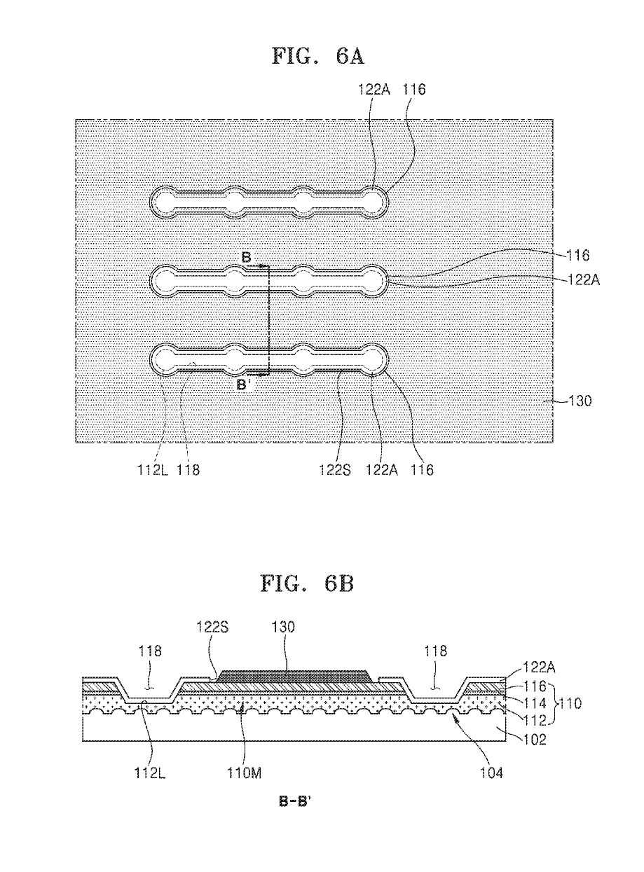

Referring to FIGS. 6A and 6B, the first insulating film 122 may be partially etched, thereby forming a preliminary first insulating pattern 122A, which exposes the top surface of the second semiconductor layer 116. The preliminary first insulating pattern 122A has a sidewall 122S defining a region of the second semiconductor layer 116 which is exposed.

After the preliminary first insulating pattern 122A is formed, the bottom surfaces of the plurality of trenches 118, and a sidewall of the mesa structure 110M defining the plurality of trenches 118 may remain covered with the preliminary first insulating pattern 122A. In addition, a portion of the top surface of the second semiconductor layer 116 around each of, or at least one of plurality of trenches 118 may remain covered with the preliminary first insulating pattern 122A, the second semiconductor layer 116 constituting the mesa structure 110M.

Next, the reflective electrode layer 130 may be formed on the top surface of the second semiconductor layer 116. To form the reflective electrode layer 130, a directed vapor deposition (DVD) process using electron beam evaporation may be performed. After the reflective electrode layer 130 is formed, the top surface of the second semiconductor layer 116 may be exposed between the sidewall 122S of the preliminary first insulating pattern 122A and the reflective electrode layer 130.

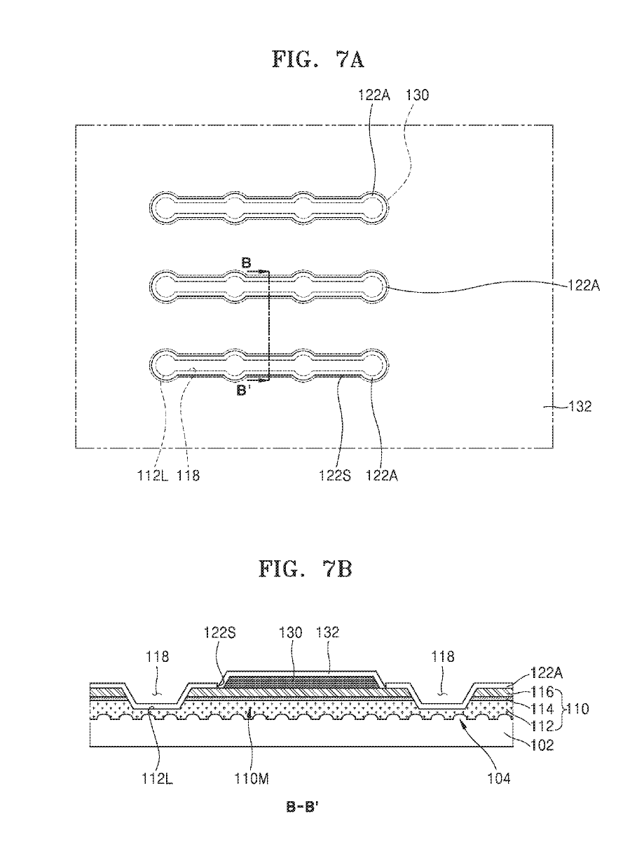

Referring to FIGS. 7A and 7B, the insulating capping layer 132 may be formed so as to cover the reflective electrode layer 130 on the second semiconductor layer 116 of the mesa structure 110M.

The insulating capping layer 132 may cover the top surface of the second semiconductor layer 116 between the sidewall 122S of the preliminary first insulating pattern 122A and the reflective electrode layer 130.

The insulating capping layer 132 may include SiO₂, Si₃N₄, MgF₂, or combinations thereof, without being limited thereto. In some example embodiments, the insulating capping layer 132 may include a material that is the same as a material constituting the first insulating film 122.

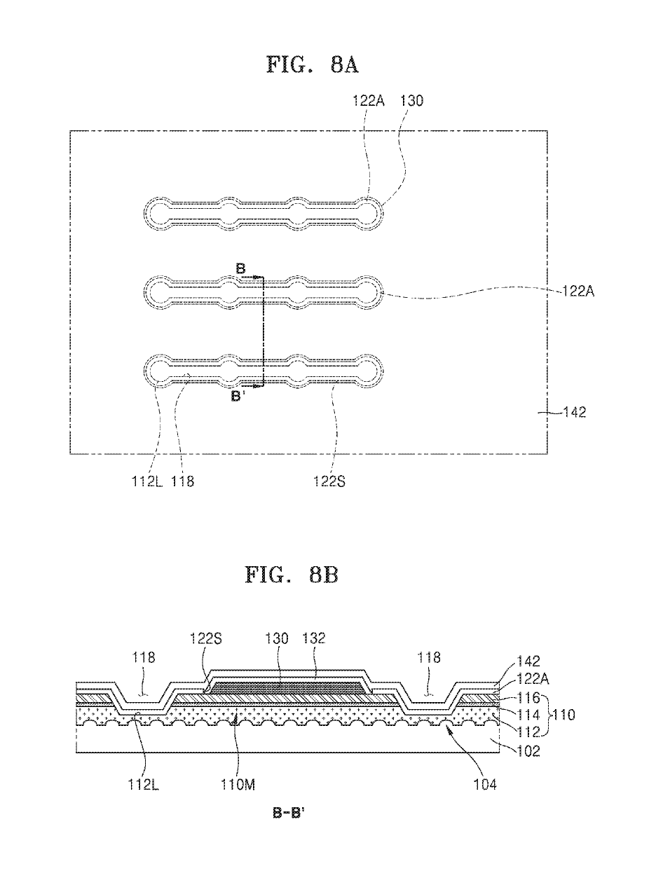

Referring to FIGS. 8A and 8B, a second insulating film 142 may be formed on a whole surface of the resulting product in which the insulating capping layer 132 covering the reflective electrode layer 130 is formed.

The second insulating film 142 may include SiO₂, Si₃N₄, or combinations thereof. The second insulating film 142 may be formed by a process of PECVD, PVD, or spin coating. In some example embodiments, the second insulating film 142 may include a different material from the material constituting the first insulating film 122. In some other example embodiments, although including the same material as the material constituting the first insulating film 122, the second insulating film 142 may be formed by a different film forming process from a film forming process used to form the first insulating film 122. For example, the first insulating film 122 may be formed by a PECVD process, and the second insulating film 142 may be formed by a PVD process. Alternatively, the first insulating film 122 may be formed by a PVD process, and the second insulating film 142 may be formed by a PECVD process. In some example embodiments, the material constituting the second insulating film 142 may have a higher refractive index than the material constituting the first insulating film 122.

In one example, each of, or at least one of the first insulating film 122 and the second insulating film 142 may include SiO₂. In another example, the first insulating film 122 may include MgF₂, and the second insulating film 142 may include SiO₂. In a further example, the first insulating film 122 may include SiO₂, and the second insulating film 142 may include Si₃N₄. However, the inventive concepts are not limited to the materials set forth above as examples.

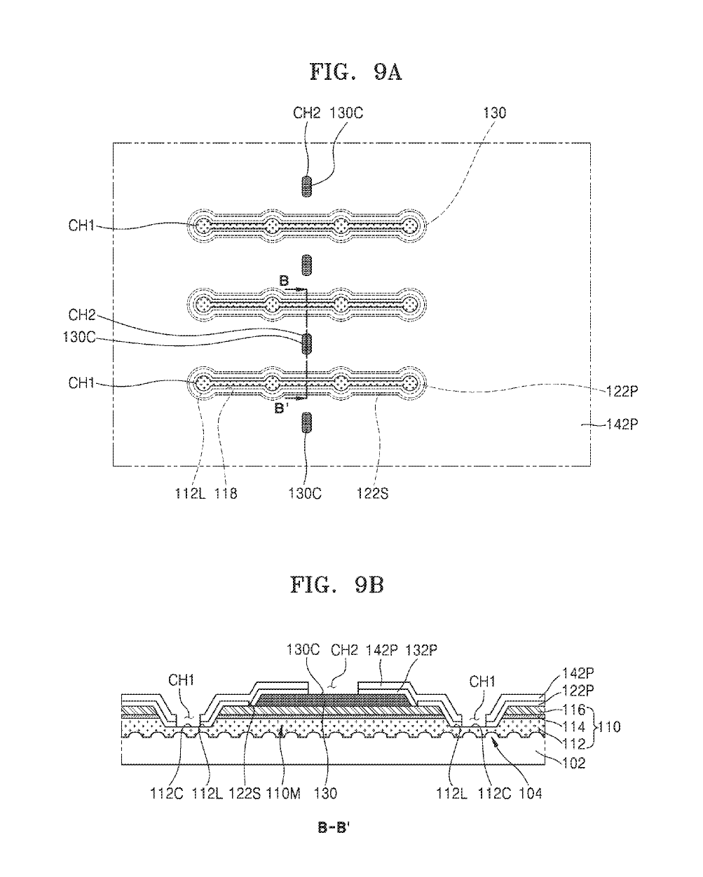

Referring to FIGS. 9A and 9B, each of, or at least one of the preliminary first insulating pattern 122A, the second insulating film 142, and the insulating capping layer 132 may be partially etched, thereby respectively forming the first insulating pattern 122P, the second insulating pattern 142P, and the insulating capping pattern 132P.

The first insulating pattern 122P and the second insulating pattern 142P may define a first contact hole CH1 exposing the contact region 112C of the low surface 112L, and the insulating capping pattern 132P and the second insulating pattern 142P may define a second contact hole CH2 exposing the contact region 130C of the top surface of the reflective electrode layer 130.

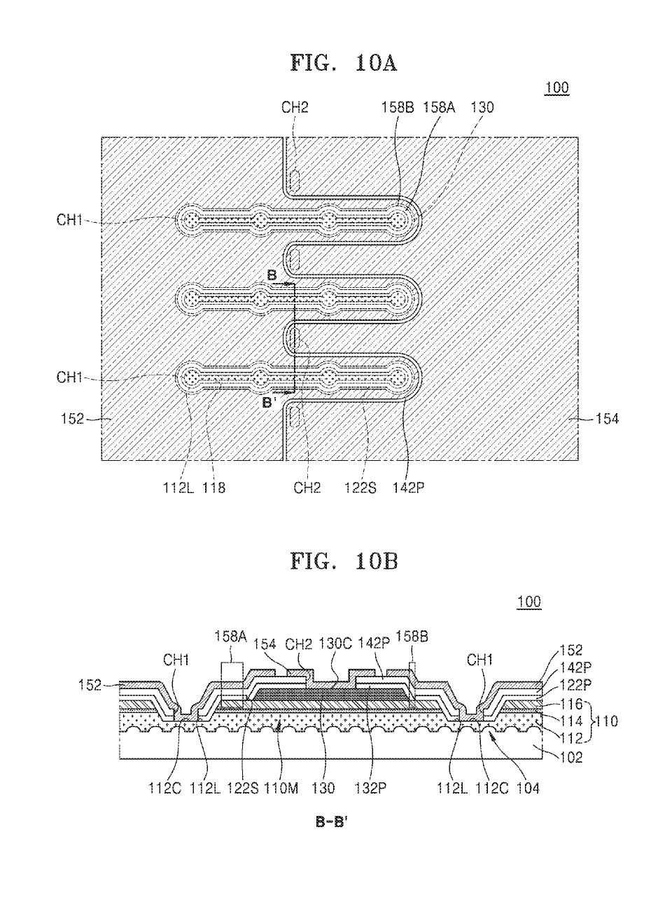

Referring to FIGS. 10A and 10B, the first interconnection conductive layer 152, which contacts the contact region 112C of the first semiconductor layer 112 through the first contact hole CH1, and the second interconnection conductive layer 154, which contacts the contact region 130C of the reflective electrode layer 130 through the second contact hole CH2, are formed.

The first interconnection conductive layer 152 may extend so as to cover the low surface 112L of the first semiconductor layer 112 and the sidewall and top surface of the mesa structure 110M. In addition, the first interconnection conductive layer 152 may extend so as to cover a portion of the top surface of the second semiconductor layer 116 of the mesa structure 110M, which is not covered with the reflective electrode layer 130, and a portion of the top surface of the reflective electrode layer 130.

The first interconnection conductive layer 152 and the second interconnection conductive layer 154 may be formed simultaneously or contemporaneously. In an example process of forming the first interconnection conductive layer 152 and the second interconnection conductive layer 154, an interconnection conductive layer may be formed on a whole surface of the resulting product, in which the low surface 112L of the first semiconductor layer 112 is exposed by the first contact hole CH1 and the reflective electrode layer 130 is exposed by the second contact hole CH2, and then the interconnection conductive layer may be etched so as to separate the interconnection conductive layer into the first interconnection conductive layer 152 and the second interconnection conductive layer 154.

Each of, or at least one of the first interconnection conductive layer 152 and the second interconnection conductive layer 154 may include a reflective metal film contacting a top surface of the second insulating pattern 142P. The reflective metal film, in conjunction with the first insulating pattern 122P, the second insulating pattern 142P, and the insulating capping pattern 132P, may constitute an ODR structure.

The ODR structure may include the first local ODR structure 158A and the second local ODR structure 158B. The first local ODR structure 158A may include a portion of each of, or at least one of the first insulating pattern 122P, the second insulating pattern 142P, and the first interconnection conductive layer 152, arranged over the top surface of the mesa structure 110M and overlapping the top surface of the second semiconductor layer 116 around the reflective electrode layer 130.

The second local ODR structure 158B may include another portion of each of, or at least one of the insulating capping pattern 132P, the second insulating pattern 142P, and the first interconnection conductive layer 152, arranged over the top surface of the mesa structure 110M and overlapping the top surface of the second semiconductor layer 116 around the reflective electrode layer 130.

Although the method of fabricating the semiconductor light-emitting device 100 shown in FIGS. 1A and 1B has been described with reference to FIGS. 3A to 10B, semiconductor light-emitting devices having various structures according to embodiments may be fabricated by modifying and changing the method described with reference to FIGS. 3A to 10B without departing from the spirit and scope of the inventive concepts. For example, to fabricate the semiconductor light-emitting device 200 shown in FIG. 2, similar or identical processes to the processes described with reference to FIGS. 3A to 10B may be performed. However, in the process described with reference to FIGS. 8A and 8B, a double-layer-structured second insulating film (not shown) including a lower second insulating film and an upper second insulating film may be formed instead of the second insulating film 142. Although the lower second insulating film and the upper second insulating film may respectively include different materials selected from SiO₂ and Si₃N₄, the inventive concepts is not limited thereto. Next, the processes described with reference to FIGS. 9A to 10B may be performed, thereby fabricating the semiconductor light-emitting device 200 shown in FIG. 2.

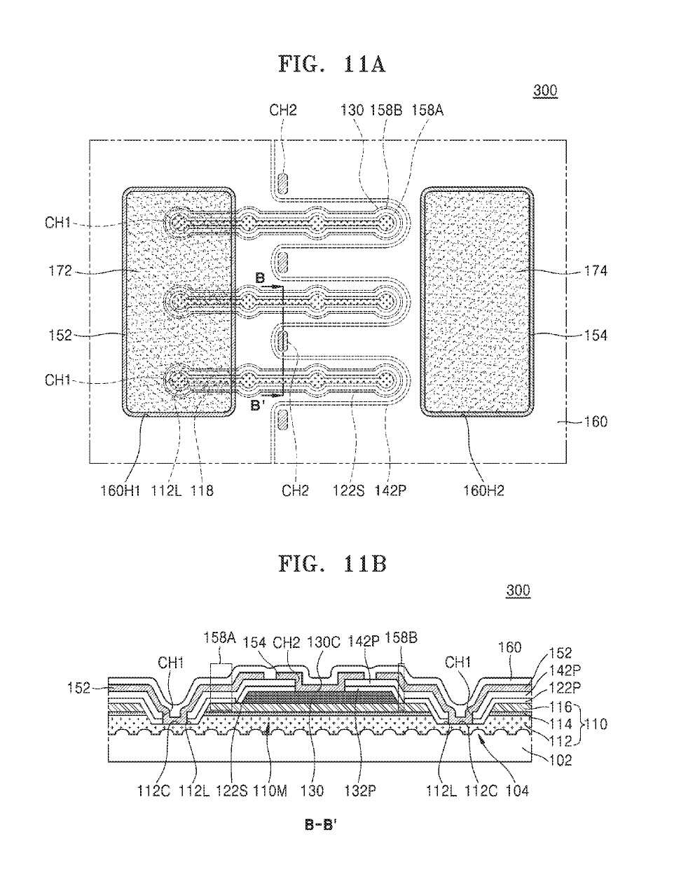

FIGS. 11A and 11B are diagrams illustrating a semiconductor light-emitting device according to further embodiments, and in particular, FIG. 11A is a plan view illustrating main components of a semiconductor light-emitting device 300 and a method of fabricating the semiconductor light-emitting device 300, and FIG. 11B is an enlarged cross-sectional view taken along a line B-B′ of FIG. 11A. In FIGS. 11A and 11B, the same reference numerals as in FIGS. 1A and 1B denote the same members, and thus further descriptions thereof are omitted for simplicity.

Referring to FIGS. 11A and 11B, the semiconductor light-emitting device 300 further includes a passivation layer 160 covering the first interconnection conductive layer 152 and the second interconnection conductive layer 154, a first bonding conductive layer 172 connected to the first interconnection conductive layer 152 through a first bonding hole 160H1 in the passivation layer 160, and a second bonding conductive layer 174 connected to the second interconnection conductive layer 154 through a second bonding hole 160H2 in the passivation layer 160, in addition to components of the semiconductor light-emitting device 100 described with reference to FIGS. 1A and 1B.

Planar shapes of the first bonding hole 160H1, the second bonding hole 160H2, the first bonding conductive layer 172, and the second bonding conductive layer 174 are not respectively limited to planar shapes shown in FIG. 11A, and may be modified and changed variously without departing from the spirit and scope of the inventive concepts.

The passivation layer 160 may include a silicon oxide film, without being limited thereto.

Each of, or at least one of the first bonding conductive layer 172 and the second bonding conductive layer 174 may include a single material selected from Au, Sn, Ni, Pb, Ag, In, Cr, Ge, Si, Ti, W, and Pt; a single-layer film that includes an alloy including at least two materials selected therefrom; or a multilayer film including combinations thereof.

In some example embodiments, each of, or at least one of the first bonding conductive layer 172 and the second bonding conductive layer 174 may include a multilayer metal film in which a Ti film, a first Ni film, a second Ni film, and an Au film are stacked in this stated order. Here, the first Ni film and the second Ni film may be Ni films formed by different deposition processes from each other. For example, the first Ni film may be a Ni film formed by a sputtering process, and the second Ni film may be a Ni film formed by a DVD process using electron beam evaporation, although the inventive concepts is not limited to the examples set forth above.

In some other example embodiments, each of, or at least one of the first bonding conductive layer 172 and the second bonding conductive layer 174 may include at least two layers selected from among a conductive barrier layer (not shown), a conductive adhesive layer (not shown), a conductive coupling layer (not shown), and a conductive bonding layer (not shown). The conductive barrier layer may include at least one selected from among a Ti layer, at least one pair of Ti/Pt double layers, at least one pair of Ti/W double layers, at least one pair of TiN/W double layers, at least one pair of W/TiW double layers, and a Ni layer. The conductive adhesive layer may include Ti. The conductive coupling layer may be formed between the conductive adhesive layer and the conductive bonding layer, and may include Ni or Ni/Au. The conductive bonding layer may include an Au—Sn alloy, a Ni—Sn alloy, a Ni—Au—Sn alloy, a Pb—Ag—In alloy, a Pb—Ag—Sn alloy, a Pb—Sn alloy, an Au—Ge alloy, or an Au—Si alloy. According to the inventive concepts, configurations of the first bonding conductive layer 172 and the second bonding conductive layer 174 are not limited to the examples set forth above, and the first bonding conductive layer 172 and the second bonding conductive layer 174 may include combinations of various conductive materials.

The semiconductor light-emitting device 300 shown in FIGS. 11A and 11B may include the second insulating pattern 242P shown in FIG. 2 instead of the second insulating pattern 142P, for example.

To fabricate the semiconductor light-emitting device 300 shown in FIGS. 11A and 11B, the processes described with reference to FIGS. 3A to 10B may be performed, and then the passivation layer 160 may be formed so as to cover the first interconnection conductive layer 152 and the second interconnection conductive layer 154. To form the passivation layer 160, various deposition processes such as CVD, PVD, and the like may be used.

Next, the first bonding hole 160H1, which exposes the first interconnection conductive layer 152, and the second bonding hole 160H2, which exposes the second interconnection conductive layer 154, may be formed by partially removing the passivation layer 160, and then, the first bonding conductive layer 172, which is connected to the first interconnection conductive layer 152 through the first bonding hole 160H1, and the second bonding conductive layer 174, which is connected to the second interconnection conductive layer 154 through the second bonding hole 160H2, may be formed.

In the semiconductor light-emitting devices 100, 200, and 300 according to the inventive concepts, which have been described with reference to FIGS. 1A to 11B, the ODR structure is provided including the first insulating pattern 122P, the second insulating pattern 142P, the insulating capping pattern 132P, and the first interconnection conductive layer 152, which cover the top surface of the second semiconductor layer 116 of the light-emitting structure 110 around the reflective electrode layer 130, thereby having a structure in which at least a portion of light emitted above a semiconductor region not covered with the reflective electrode layer 130 may be reflected by the ODR structure. Therefore, the semiconductor light-emitting devices 100, 200, and 300 allow total reflection to be maximized and luminous flux to be improved.

In addition, the semiconductor light-emitting devices 100, 200, and 300 have a structure in which the reflective electrode layer 130 is capped with the multilayer insulating structure 120. Therefore, the reliability of the reflective electrode layer 130 may be improved by reducing or suppression of migration or agglomeration of a metal material in the reflective electrode layer 130 through excellent adhesion between the semiconductor layer of the mesa structure 110M and the insulating structure 120, and the semiconductor light-emitting devices 100, 200, and 300 may have a relatively stable structure due to physically enhanced adhesion between the reflective electrode layer 130 and the mesa structure 110M.

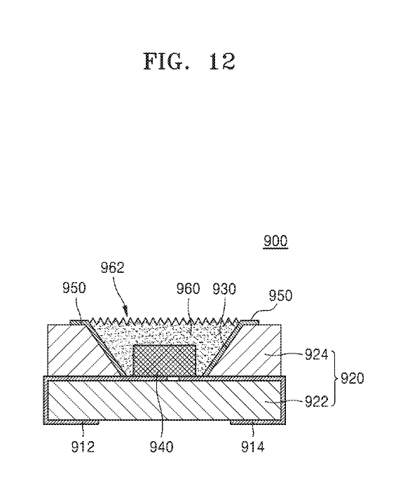

FIG. 12 is a cross-sectional view illustrating an example of a light-emitting device package including a semiconductor light emitting device including the semiconductor light emitting device according to some example embodiments.

Referring to FIG. 12, a light-emitting device package 900 may include a cup-type package structure 920 in which electrode patterns 912 and 914 are formed. The package structure 920 may include a lower substrate 922 including the electrode patterns 912 and 914 on a surface thereof, and an upper substrate 924 having a groove 930.

A semiconductor light-emitting device 940 may be mounted on a bottom surface of the groove 930 in the manner of flip chip. The semiconductor light-emitting device 940 may include at least one of the semiconductor light-emitting devices 100, 200, and 300 and semiconductor light-emitting devices modified and changed therefrom without departing from the spirit and scope of the inventive concepts.

The semiconductor light-emitting device 940 may be fixed onto the electrode patterns 912 and 914 by eutectic bonding.

A reflective plate 950 is formed on an inner sidewall of the groove 930. The semiconductor light-emitting device 940 may be covered with a transparent resin 960 which is on the reflective plate 950 and fills an inside of the groove 930. An uneven pattern 962 for improving light extraction efficiency may be formed on a surface of the transparent resin 960. In some example embodiments, the uneven pattern 962 may be omitted.

The light-emitting device package 900 may be used as a blue LED having high power/high efficiency, and the blue LED may be used to realize large-size displays, LED TVs, RGB white illumination, emotional lighting, and the like.

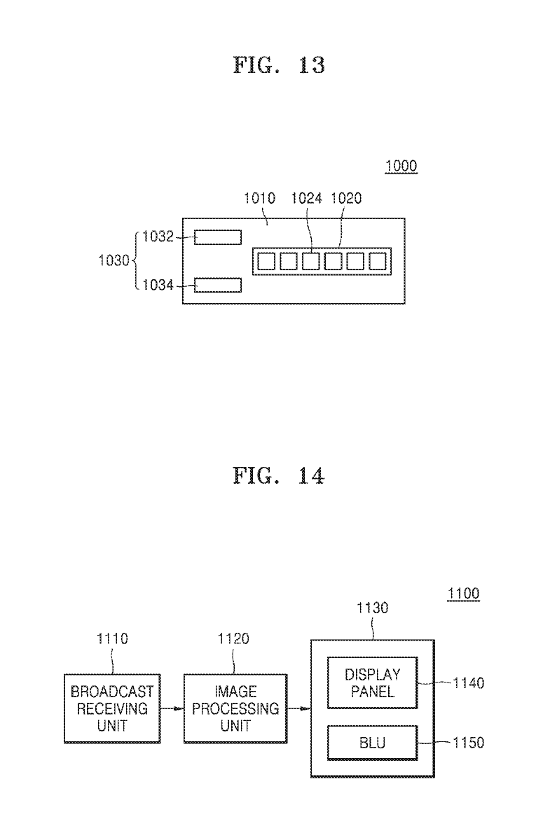

FIG. 13 is a schematic plan view illustrating an example of a dimming system including a semiconductor light-emitting device according to some example embodiments.

Referring to FIG. 13, a dimming system 1000 may include a light-emitting module 1020 and a power supply 1030, which are arranged on a structure 1010.

The light-emitting module 1020 may include a plurality of light-emitting device packages 1024. The plurality of light-emitting device packages 1024 may include at least one of the semiconductor light-emitting devices 100, 200, and 300 and semiconductor light-emitting devices modified and changed therefrom without departing from the spirit and scope of the inventive concepts.

The power supply 1030 may include an interface 1032, to which power is input, and a power controller 1034 controlling power supplied to the light-emitting module 1020. The interface 1032 may include a fuse cutting off over-current, and an electromagnetic wave shielding filter shielding electromagnetic interference signals. The power controller 1034 may include a rectifier and a smoothing unit so that alternating current (AC) may be converted into direct current (DC) when AC power is input as power, and may also include a constant voltage controller converting an input voltage into a voltage suitable for the light-emitting module 1020. The power supply 1030 may include a feedback circuit device comparing an amount of light emitted from the plurality of light-emitting device packages 1024 with a pre-set amount of light, and a memory device storing information such as desired brightness, color rendering, and the like.

In some example embodiments, the dimming system 1000 may be applied to backlight units used in displays, such as liquid crystal displays including image panels; indoor illumination devices such as lamps or flat illumination devices; or outdoor illumination devices such as street lamps, signboards, or signposts. In some other example embodiments, the dimming system 1000 may be applied to illumination devices for various vehicles, for example, illumination devices for automobiles, ships, or aircraft, household appliances such as TVs or refrigerators, medical devices, or the like.

FIG. 14 is a block diagram of a display device 1100 including a semiconductor light-emitting device according to some example embodiments.

Referring to FIG. 14, the display device 1100 may include a broadcast receiving unit 1110, an image processing unit 1120, and a display 1130.

The display 1130 may include a display panel 1140 and a backlight unit (BLU) 1150. The BLU 1150 includes light sources generating light, and driving devices driving the light sources.

The broadcast receiving unit 1110, which is a device selecting a channel of a broadcast received in a wireless or wired manner through air or a cable, allows an arbitrary channel among a plurality of channels to be set as an input channel, and receives a broadcast signal of the channel set as the input channel.

The image processing unit 1120 performs signal processing, such as video decoding, video scaling, frame rate conversion (FRC), or the like, on broadcast content output from the broadcast receiving unit 1110.

The display panel 1140 may include a liquid crystal display (LCD) panel, without being limited thereto. The display panel 1140 displays broadcast content signal-processed by the image processing unit 1120. The BLU 1150 allows the display panel 1140 to display images by projecting light onto the display panel 1140. The BLU 1150 includes at least one of the semiconductor light-emitting devices 100, 200, and 300, which have been described with reference to FIGS. 1A to 11B, and semiconductor light-emitting devices modified and changed therefrom without departing from the spirit and scope of the inventive concepts.

While the inventive concepts has been particularly shown and described with reference to embodiments thereof, it will be understood that various changes in form and details may be made therein without departing from the spirit and scope of the following claims.

1. A semiconductor light-emitting device comprising:
a light-emitting structure including a first semiconductor layer, an active layer, and a second semiconductor layer;
a reflective electrode layer covering a top surface of the second semiconductor layer;
an insulating structure covering a region of the top surface of the second semiconductor layer, the region being around the reflective electrode layer;
a first interconnection conductive layer in contact with a contact region of the first semiconductor layer through the insulating structure, an omni-directional reflector (ODR) structure being formed by the first interconnection conductive layer and the insulating structure; and
a second interconnection conductive layer contacting the reflective electrode layer through the insulating structure.

2. The semiconductor light-emitting device according to claim 1, wherein the ODR structure has a ring shape surrounding the contact region of the first semiconductor layer.

3. The semiconductor light-emitting device according to claim 1, wherein the insulating structure comprises:
a first insulating pattern covering a region of the top surface of the second semiconductor layer, the region being around the reflective electrode layer; and
a second insulating pattern on the first insulating pattern, the second insulating pattern covering the reflective electrode layer and the top surface of the second semiconductor layer,
wherein the ODR structure includes a first local ODR structure including the first insulating pattern, the second insulating pattern, and the first interconnection conductive layer.

4. The semiconductor light-emitting device according to claim 3, wherein the first insulating pattern is in contact with the top surface of the second semiconductor layer, and
a refractive index of the first insulating pattern is less than a refractive index of the second insulating pattern.

5. The semiconductor light-emitting device according to claim 3, wherein the first interconnection conductive layer is in contact with the contact region of the first semiconductor layer through the first insulating pattern and the second insulating pattern.

6. The semiconductor light-emitting device according to claim 3, wherein the first local ODR structure is between the contact region of the first semiconductor layer and the reflective electrode layer and has a ring shape surrounding the contact region of the first semiconductor layer.

7. The semiconductor light-emitting device according to claim 3, wherein the insulating structure further includes an insulating capping pattern between the reflective electrode layer and the second insulating pattern and between the top surface of the second semiconductor layer and the second insulating pattern, and
the ODR structure further includes a second local ODR structure comprising the insulating capping pattern, the second insulating pattern, and the first interconnection conductive layer.

8. The semiconductor light-emitting device according to claim 7, wherein the second interconnection conductive layer is in contact with the reflective electrode layer through the insulating capping pattern and the second insulating pattern.

9. The semiconductor light-emitting device according to claim 7, wherein the second local ODR structure is between the reflective electrode layer and the first local ODR structure and has a ring shape surrounding the contact region of the first semiconductor layer.

10. The semiconductor light-emitting device according to claim 7, wherein the insulating capping pattern is in contact with the top surface of the second semiconductor layer, and
a refractive index of the insulating capping pattern is less than a refractive index of the second insulating pattern.

11. A semiconductor light-emitting device comprising:
a light-emitting structure including a first semiconductor layer, an active layer, and a second semiconductor layer;
a reflective electrode layer covering a first region of a top surface of the second semiconductor layer;
a first insulating pattern covering a second region of the top surface of the second semiconductor layer, the second region being around the first region;
a second insulating pattern covering the first insulating pattern and the reflective electrode layer on the top surface of the second semiconductor layer;
a first interconnection conductive layer, in contact with a contact region of the first semiconductor layer through the first insulating pattern and the second insulating pattern and facing the top surface of the second semiconductor layer with the first insulating pattern and the second insulating pattern being between the first interconnection conductive layer and the top surface of the second semiconductor layer, a first local ODR structure being formed by the first interconnection conductive layer, the first insulating pattern and the second insulating pattern; and
a second interconnection conductive layer contacting the reflective electrode layer through the second insulating pattern and apart from the first interconnection conductive layer.

12. The semiconductor light-emitting device according to claim 11, wherein the first insulating pattern is in contact with the second region of the second semiconductor layer, and
a refractive index of the first insulating pattern is less than a refractive index of the second insulating pattern.

13. The semiconductor light-emitting device according to claim 11, further comprising:
an insulating capping pattern covering a third region of the top surface of the second semiconductor layer, the third region being between the first region and the second region,
wherein a second local ODR structure is formed by the first interconnection conductive layer, the insulating capping pattern and the second insulating pattern.

14. The semiconductor light-emitting device according to claim 13, wherein the insulating capping pattern is in contact with the third region of the second semiconductor layer, and
a refractive index of the insulating capping pattern is less than a refractive index of the second insulating pattern.

15. The semiconductor light-emitting device according to claim 11, wherein the first local ODR structure is between the contact region of the first semiconductor layer and the reflective electrode layer and has a ring shape surrounding the contact region of the first semiconductor layer.

16. A semiconductor light-emitting device comprising:
a light-emitting structure;
a reflective electrode layer on the light-emitting structure;
an omni-directional reflector (ODR) structure including a first interconnection conductive layer and an insulating structure, the insulating structure being on a region of the light-emitting structure around the reflective electrode layer; and
a second interconnection conductive layer in contact with the reflective electrode layer through the insulating structure.

17. The semiconductor light-emitting device according to claim 16, wherein the light-emitting structure comprises a first semiconductor layer, an active layer, and a second semiconductor layer.

18. The semiconductor light-emitting device according to claim 17, wherein the reflective electrode layer is on the second semiconductor layer.

19. The semiconductor light-emitting device according to claim 17, wherein the first interconnection conductive layer is in contact with a contact region of the first semiconductor layer through the insulating structure.

20. The semiconductor light-emitting device according to claim 19, wherein the ODR structure has a ring shape surrounding the contact region of the first semiconductor layer.
